(19) United States
(12) Patent Application Publication
(10) Pub. No.: US 2007/0052426 A1
(43) Pub. Date: Mar. 8, 2007

(54) On-line transformer condition monitoring

(76) Inventors: Charles H. Wells, Emerald Hills, CA (US); Robert Broadwater, Blacksburg, VA (US)

Correspondence Address: LUMEN INTELLECTUAL PROPERTY SERVICES, INC., 2345 YALE STREET, 2ND FLOOR, PALO ALTO, CA, 94306, US

(21) Appl. No.: 11/495,180

(22) Filed: Jul. 28, 2006

Related U.S. Application Data
(60) Provisional application No. 60/704,820, filed on Aug. 1, 2005.

(51) Int. Cl. G01R 31/06

(52) U.S. Cl. 324/547

(57) ABSTRACT

This invention is used to determine the condition of power transformers using real-time on-line high speed measurements. Specifically, a failure prediction method is described. This provides alerts prior to a catastrophic event that could cause major damage to the transformer and resulting business losses. Real time absolute phase angle and frequency as well as real and reactive power measurements from both sides of the transformer are used to estimate frequency domain transfer functions. The transfer functions are in fact the complex admittance functions relating the input and the outputs from the transformer. Three methods of computing the transfer function are outlined in this application. First, the Fast Fourier Transform (FFT) of both the input and the output wave forms are used to compute the transfer functions continuously in real time. Transfer functions have been used for many years to characterize the health of the transformer; however, historically this has been done with the transformer disconnected from the circuit, and using low voltage impulse function testing methods (Doble). The FFT of the impulse response represents the transfer function in the complex frequency domain. Second, the auto-regressive moving average methods to perform this function may be used, and third, a spectral band comparison. And a third “comb” method is also demonstrated as an approximation to the transfer function method.

### RELATED APPLICATIONS

This application claims priority under 35 U.S.C. §119(e) to provisional application No. 60/704,820 filed on Aug. 1, 2005 titled “On-Line Transformer Condition Monitoring.”

### FIELD

The invention relates to testing power transformers, and, more particularly, to testing the condition of transformers while they are in use.

### BACKGROUND

Power transformers are generally removed from service before being tested. Prior art testing may be performed using low voltage impulse function testing methods (Doble). The prior art method of disconnecting a transformer from the power grid before testing it can be time consuming and costly.

### SUMMARY

By using real time absolute phase angle, frequency, real power, and reactive power measurements from both sides of a transformer that is on-line, one can estimate frequency domain transfer functions. These transfer functions can be used to estimate the relative health of the transformer. Thus, potentially problematic transformers can be detected and removed from the power grid, and the detection can be accomplished without bringing the transformers off-line.

The detection methods may include the use of fast Fourier transforms (FFT's), autoregressive moving averages, and/or spectral band comparisons (Comb comparisons).

### BRIEF DESCRIPTION OF DRAWINGS

FIGS. 1A-C show examples of one, two, and three phase transformers.

FIG. 2 shows an example of an on-line transformer monitor.

### DESCRIPTION

The shape of the transfer function spectrum provides real time indicators of the health of the transformer indicating age, wear, winding movement, or dielectric strength changes. The parameters in the transfer function are value and rate tested, and then plotted in parameter space. A region of normal operation is determined when the invention is first applied to a normally operating transformer.

Three methods of identifying the transfer functions of the transformer area specified. The first is based on Fourier Transform technology (effectively the same as Laplace transforms) and the second is based on Box and Jenkins method, sic autoregressive moving average methods and the third involves using the harmonic magnitudes of the input and output waveforms directly. We outline the approaches below.

A: Fourier Transform (Laplace Transform Representations)

Linear systems can be represented as follows:
y(s)=K(s)·x(s)
where y(s) is Laplace transform of the output side of the transformer, x(s) is the input side of the transformer, and K(s) is the transfer function. This applies to both step down and step up transformers. The (s) domain (Laplace) is used for illustration purposes rather that the frequency domain (ω), since the two representations are essentially equivalent, also (s) is easier to type and readers are generally more familiar with the Laplace domain.

In our invention, we measure and compute the y(s) and x(s) functions in real time using FFT's; hence, we can compute the K(s) by either long division or partial fraction expansion. The coefficients of the transfer function provide information about the dynamic characteristics of the transformer and its shape also provided real time information about the condition of the transformer. Algorithms for both long division and partial fraction expansion exist and are relevant to this invention.

For the implementation of this invention for transforms, we will discuss a typical solution. This invention is NOT limited to transformers, but applies to any process with a single input and output.

Suppose the output and input wave forms are sampled at 20 Hz and a 1024 point moving window FFT is computed each 50 msec. That is a new FFT is computed 20 times per second. The FFT's consist of real and imaginary parts, but for our on-line identification invention, we take the magnitude of the complex number and represent FFT as a polynomial in the complex domain with coefficients equal to the magnitude of the FFT at each shift interval. The DC value is the constant part of the polynomial and the first shift is the coefficient of the first order term in the polynomial.

For illustration purposes, suppose the FFT of the output has magnitude values of 3, 4, 2, 3 and the input values are 3, 3, and 1. For this case, the polynomial becomes:

$$K ( s ) = \frac{3 {s}^{2} + 2 {s}^{2} + 4 s + 3}{{s}^{2} + 3 s + 3}$$

We are interested in quotient of this polynomial. Using long division, the quotient is:

$$K ( s ) = 3 s - 7 + \frac{16 s + 18}{{s}^{2} + 3 s + 3}$$

where the last term is the remainder. The parameters describing the transformer are 3 and 7. The number (3) represents the time constant and the number (−7) represents the gain. These numbers represent the dynamic behavior of the system and in some sense are the gain and time constant of first order representation of the system. If these numbers change their values, then the transformer transfer characteristics are changing. For this invention, synthetic long division of the output FFT divided by the input FFT yields the transfer function directly. This function is exactly equivalent to the open circuit Doble testing method. However, it is done continually on-line at periods of 50 ms, the sample rate of phasor measurement units. The coefficients of the synthetic division represent the sample spectrum as obtained by the Doble methods, and hence will have a characteristic shape defining the current conditions of the transformer. We expect a trained Doble observer would be able to recognize the same patterns as seen in the static testing case.

Each power transformer has multiple independent measurements including: volts and current on each phase, absolute angle for volts and current on each phase, frequency, real and reactive power. There will be a transfer function for each independent pair as well as a transfer function across pairs. For example, the real power inputs vs. the reactive power output. Using this concept, the multi-variable transfer function components can be identified. In order to display the current state of the transformer, we use X-Y diagrams to plot the trajectories of the parameters in the transfer function. The x axis would represent the DC component and the y axis would represent the first order component. We also cross-correlate the values and display a linear fit to the past values of the transfer function coefficients. Any change to the slope of this line represents a change in the characteristics of the transformer. Similarly, a bounding box in the coefficient space can be used to identify when the transformer is failing. An alarm is emitted when the parameters exceed the bounding box. There will also be general alarms in magnitudes and rates of change, but these are not part of the invention B. Autoregressive Moving Average: ARMA model A similar technique can be used based on classic methods in forecasting and statistics. This is the ARMA approach outlined in Box and Jenkins. In this case the transfer function is a difference equation of the form:
yₙ=a₁yₙ₋₁+a₂yₙ₋₂+. . .+aₙ₋ₗyₙ₋ₗ+b₀xₙ₋₀+bₗxₙ₋₁+. . .+bₙ₋ₗxₙ₋ₖ
where 1 is the order of the autoregressive portion and k is the order of the moving average portion and n is time “now.” The value of 1 can be estimated by autocorrelating differences in the y values until they are white noise. For example if it takes three successive differences to obtain white noise, then it can be assumed that the autoregressive term is third order. In cases where there is either measurement delay or process delay, the pure time delay can be estimated by computing the cross correlation function between the input and the output. The values of the coefficients can be found by using moving window least squares fitting technology. Recursion is NOT used, but true moving windows, with each new window requiring the inversion of a (1+k) matrix. The least squares fitting can be represented as:
yₙ=a₁yₙ₋₁+a₂yₙ₋₂+. . .+aₙ₋ₗyₙ₋ₗ+b₀xₙ₋₀+bₗxₙ₋₁+. . .+bₙ₋ₗxₙ₋ₖ
yₙ₋₁=a₁yₙ₋₂+a₂yₙ₋₃+. . .+aₙ₋ₗyₙ₋₁₋ₗ+b₀xₙ₋₁+bₗxₙ₋₂+. . .+bₙ₋ₗxₙ₋ₗ₋ₖ
yₙ₋ᵢ=a₁yₙ₋ᵢ₋₁+a₂yₙ₋ᵢ₋₂+. . .+aₙ₋ₗyₙ₋ᵢ₋ₗ+b₀xₙ₋ᵢ+bₗxₙ₋ᵢ₋₁+. . .+bₙ₋ₗxₙ₋ᵢ₋ₖ
where i>1+k is the history length used in the least squares fitting.

Where p is the column vector of a's and b's coefficients, with the coefficients in the top (1) rows followed by the b coefficients in the bottom (k) rows, and the [A] (i, (1+k)) matrix containing the rows of measurements of y and x values over time. The rank of this matrix may be less than (1+k); however, this does not present problems in this invention, as mentioned below. The number of past samples, (i), must equal or exceed (1+k). In cases where the matrix is ill conditioned, the principal component analysis method is used to solve for the least squares parameter estimates.

The best estimate of the parameters is given by
\hat{p}=[A^{T}A]⁻¹A^{T}y

The values of the parameters are of interest. If these values move dramatically, the transfer function of the transformer has changed. This function would be done for each of the input-output pairs as well as all of the cross pairings.

Input-Output Measurements:

For each transformer we can measure the following properties of the input and output: angle of volts and current on the three phases, real and reactive power on the three phases, frequency, and a number of other power quality measurements. However, the most important variables are the phasor information and frequency: i.e., magnitude and absolute angle of each phase voltage and current. The power flow can be derived from these fundamental measurements. The transfer functions under discussion are:

$${K}_{Va} ( s ) = \frac{{V}_{aO} ( S )}{{V}_{al} ( s )}$$

Where Vₐ represents the voltage transfer function on phase a, and the subscript O and I represent Output and Input terminals of the transformer. There are other transfer functions including: V_{b}, V_{c}, Iₐ, I_{b}, I_{c}, also the cross transfer functions, V_{ab}, V_{ac}, I_{ab}, I_{ac}. The cross transfer functions are for example, V_{ab} represents the output of phase a with an input of phase b; i.e., the cross-talk coupling between coils of the transformer. Additional transfer functions include the real and reactive power transfer functions. These would be represented by Pₐ, P_{b}, P_{c}, P_{ab}, P_{ac}, P_{ba}, P_{bc}, P_{ca}, and Pcb for both real and reactive power.

C. Spectral Band Comparison (Comb Comparisons)

This portion of the invention is based on the same principals that are used in Doble testing except there is no harmonic excitation; rather the natural frequencies of the grid disturbances contain the excitation. This method is an approximation to the method outlined in (A).

We specifically are looking at the damping characteristics of the transformer in 100 ms and up periods.

Let Y(h) be the output FFT magnitudes at harmonic numbers, h and X(h) the FFT magnitudes. The FFT will contain peaks at fundamental frequency as well as both harmonics and sub-harmonics of the AC wave form. Let

$$K ( h ) = \frac{Y ( h )}{X ( h )}$$

For a typical 1024 array FFT, the period at h=1 is 50 ms. Thus K(1) is the gain relationship between the input and the output at harmonic number (1); i.e., if the input excitation were a pure sine wave with a period of 50 ms. The value of K(2) is at twice the period, etc. The raw sensor measurements for example compute the first 50 harmonics. In this case, we simply divide the output harmonic by the corresponding input harmonics numbers. Note, this method does not require long division, and hence is faster that method (A).

For example, in the Arbiter 1133A power quality meter the first 50 harmonics are generated each second. Thus a new transfer function could be calculated with 50 division operations. Since the Arbiter has 6 channels computing harmonics, a complete system could be implemented with a single Arbiter 1133A measuring three voltages on the input and three voltages on the output could be obtained from a single Arbiter 1133A.

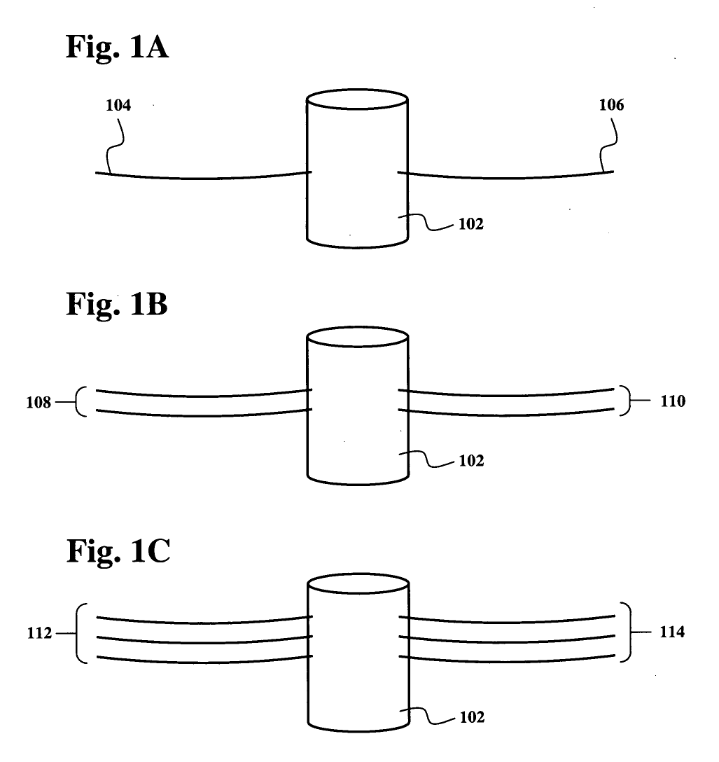

FIGS. 1A-C show examples of one, two, and three phase transformers. FIG. 1A shows a transformer 102 with input line 104 and output line 106. FIG. 1B shows a transformer 102 with input line 108 and output line 110. FIG. 1C shows a transformer 102 with input line 112 and output line 114. For the purposes of this application, the term one input electronic signal comprises a signal at any of the inputs 104, 108, 112. Likewise, the term one output electronic signal comprises a signal at any of the outputs 106, 110, 114.

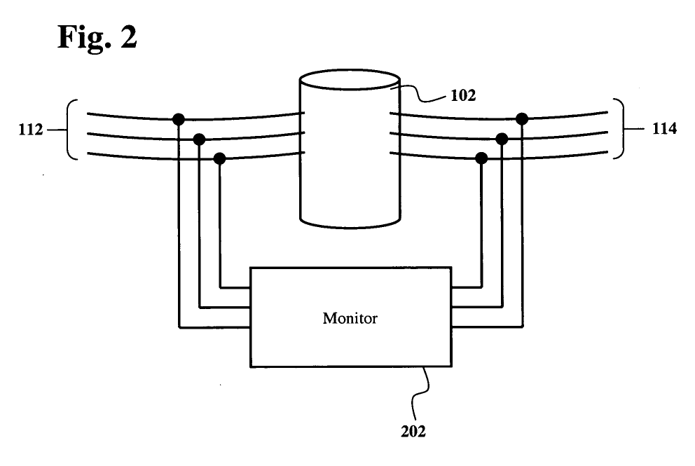

FIG. 2 shows an example of an on-line transformer monitor. Shown are a transformer 102 with input line 112, output line 114, and a monitor 202. The monitor 202 examines the input signal on the input line 112 and the output signal on the output line 114 to determine whether or not the transformer is healthy.

One example of a real time implementation uses a 3 minute moving window with sampling rate of 50 ms intervals. This is the default rate for the PMU's that are used as the instruments. A quad processor server can be used as the computer and the FFT algorithm can be one like the Intel MLK 8 suite of analytic software. Computing the FFT can be done with any fast algorithm, such as FFT-W from MIT, but the Intel algorithm may be faster for longer windows.

It will be apparent to one skilled in the art that the described embodiments may be altered in many ways without departing from the spirit and scope of the invention. Accordingly, the scope of the invention should be determined by the following claims and their equivalents.

What is claimed is:

1. An electronic device testing system comprising:
a signal monitoring unit, the signal monitoring unit measuring one input electronic signal and one output electronic signal of the electronic device,
where the testing system monitors a health of the electronic device while the electronic device is in use,
where the testing system computes a transfer function of the electronic device, and
where the testing system determines the health of the electronic device based on the transfer function.

2. The system of claim 1, where the electronic device is an electrical transformer.

3. The system of claim 1, where the testing system uses fast Fourier transforms to compute the transfer function.

4. The system of claim 1, where the testing system uses an autoregressive moving average to compute the transfer function.

5. The system of claim 1, where the testing system uses spectral band comparison to compute the transfer function.

6. The system of claim 1, where the testing system alerts an operator when the electronic device is determined to be unhealthy.

7. The system of claim 1,
where a region of normal operation is determined by the transfer function of the electronic device which is known to be operating normally, and
where a transfer function that exceeds a bounds of the region may indicate that the electronic device is unhealthy.
